(19) United States
(12) Patent Application Publication
(10) Pub. No.: US 2019/0013353 A1
(43) Pub. Date: Jan. 10, 2019

(54) APPROACHES FOR INTEGRATING STT-MRAM MEMORY ARRAYS INTO A LOGIC PROCESSOR AND THE RESULTING STRUCTURES

(71) Applicant: Intel Corporation, Santa Clara, CA (US)

(72) Inventors: Kevin J. LEE, Beaverton, OR (US); Oleg GOLONZKA, Beaverton, OR (US); Tahir GHANI, Portland, OR (US); Ruth A. BRAIN, Portland, OR (US); Yih WANG, Portland, OR (US)

(21) Appl. No.: 16/067,801

(22) PCT Filed: Mar. 7, 2016
(86) PCT No.: PCT/US2016/021243

§ 371 Date: Jul. 2, 2018

(51) Int. Cl. H01L 27/22; H01L 43/08; H01L 43/12; H01L 23/532; G11C 11/16; H01L 23/522

(52) U.S. Cl. CPC H01L 27/228; H01L 43/08; H01L 43/12; H01L 21/76832; G11C 11/16; H01L 23/5226; H01L 23/5329

(57) ABSTRACT

Approaches for integrating spin torque transfer magnetic random access memory (STT-MRAM) memory arrays into a logic processor, and the resulting structures, are described. In an example, a logic processor including a logic region including metal line/via pairings disposed in a dielectric layer disposed above a substrate. The logic processor also includes a spin torque transfer magnetoresistive random access memory (STT-MRAM) array including a plurality of magnetic tunnel junctions (MTJs). The MTJs are disposed in the dielectric layer.

### TECHNICAL FIELD

Embodiments of the invention are in the field of integrated circuit fabrication and, in particular, approaches for integrating spin torque transfer magnetic random access memory (STT-MRAM) memory arrays into a logic processor, and the resulting structures.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, lending to the fabrication of products with increased capacity. The drive for ever-more capacity, however, is not without issue. The necessity to optimize the performance of each device becomes increasingly significant.

Non-volatile embedded memory, e.g., on-chip embedded memory with non-volatility can enable energy and computational efficiency. However, there may be density limitations for traditional spin torque transfer magnetoresistive random access memory (STT-MRAM) integration to accommodate large write switching current and select transistor requirements. Specifically, traditional STT-MRAM has a cell size limitation due to the drive transistor requirement to provide sufficient spin current. Furthermore, such memory is associated with large write current (>100 μA) and voltage (>0.7 V) requirements of conventional magnetic tunnel junction (MTJ) based devices.

As such, significant improvements are still needed in the area of non-volatile memory arrays based on MTJs and, in particular, in their integration with logic processors.

### BRIEF DESCRIPTION OF THE DRAWINGS

FIG. 1 illustrates a cross-sectional view of a logic region together with a STT-MRAM memory array integrated on a common substrate, in accordance with an embodiment of the present invention.

FIGS. 2A-2P illustrate cross-sectional views representing various processing operations in a method of fabricating logic regions together with STT-MRAM memory array integrated on a common substrate, in accordance with an embodiment of the present invention, wherein:

FIG. 2A illustrates a starting structure in the method of fabricating logic regions together with an STT-MRAM arrays, including M2/V1 metallization structures formed above a common substrate;

FIG. 2B illustrates the structure of FIG. 2A following formation of an etch stop layer;

FIG. 2C illustrates the structure of FIG. 2B following formation and patterning of a photoresist layer;

FIG. 2D illustrates the structure of FIG. 2C following an anisotropic dry etch process used to transfer the resist pattern into the etch stop layer;

FIG. 2E illustrates the structure of FIG. 2D following formation of a conductive metal layer;

FIG. 2F illustrates the structure of FIG. 2E following planarization to remove conductive metal overburden of the conductive metal layer;

FIG. 2G illustrates the structure of FIG. 2F following formation of a pedestal metal layer;

FIG. 2H illustrates the structure of FIG. 2G following formation of MTJ free layer film(s), tunnel barrier material, MTJ fixed layer film(s), and MTJ hard mask metallization films;

FIG. 2I illustrates the structure of FIG. 2H following formation and patterning of a photoresist layer;

FIG. 2J illustrates the structure of FIG. 2I following patterning to form an MTJ stack;

FIG. 2K illustrates the structure of FIG. 2J following formation and patterning of a photoresist layer;

FIG. 2L illustrates the structure of FIG. 2K following an anisotropic dry etch process used to transfer the resist pattern into the pedestal metal layer to form a plurality of pedestals;

FIG. 2M illustrates the structure of FIG. 2L following formation of an interlayer dielectric (ILD) layer;

FIG. 2N illustrates the structure of FIG. 2M following planarization;

FIG. 2O illustrates the structure of FIG. 2N following fabrication of M3/V2 copper interconnect structures in the logic areas of the structure; and

FIG. 2P illustrates the structure of FIG. 2O following formation of an etch stop later and an inter-layer dielectric layer.

FIG. 3 illustrates a block diagram of an electronic system, in accordance with an embodiment of the present invention.

FIG. 4 illustrates a computing device in accordance with one embodiment of the invention.

FIG. 5 illustrates an interposer that includes one or more embodiments of the invention.

### DESCRIPTION OF THE EMBODIMENTS

Approaches for integrating spin torque transfer magnetic random access memory (STT-MRAM) memory arrays into a logic processor, and the resulting structures, are described. In the following description, numerous specific details are set forth, such as specific magnetic tunnel junction (MTJ) layer regimes, in order to provide a thorough understanding of embodiments of the present invention. It will be apparent to one skilled in the art that embodiments of the present invention may be practiced without these specific details. In other instances, well-known features, such as operations associated with embedded memory, are not described in detail in order to not unnecessarily obscure embodiments of the present invention. Furthermore, it is to be understood that the various embodiments shown in the Figures are illustrative representations and are not necessarily drawn to scale.

One or embodiments of the present invention are directed to methods for integrating STT-MRAM memory arrays into a logic processor using an MTJ-first approach. Embodiments may pertain to one or more of magnetic tunnel junctions (MTJs) or spin transfer torque magnetoresistive random access memory (STT-MRAM).

To provide context, integrating memory directly onto a microprocessor chip would be advantageous since it enables much wider busses and higher operation speeds compared to having physically separate logic and memory chips. Unfortunately, traditional charge-based memory technologies such as DRAM and NAND Flash are now facing severe scalability issues related to increasingly precise charge placement and sensing requirements. As such, embedding charge-based memory directly onto a high performance logic chip is not very attractive for future technology nodes. However, a memory technology that does have the potential to scale to much smaller geometries compared to traditional charge-based memories is spin-torque transfer magnetoresistive random access memory (STT-MRAM), since it relies on resistivity rather than charge as the information carrier. However, in order to exploit the potential benefits of a high performance logic chip with embedded STT-MRAM memory, an appropriate integrated logic plus STT-MRAM structure and fabrication method is needed. Embodiments of the present invention include such structures and fabrication processes.

In accordance with one or more embodiments described herein, a structure is disclosed in which spin transfer torque random access memory (STT-MRAM) arrays, which include a multitude of magnetic tunnel junctions (MTJs), are embedded within a back-end interconnect layer of a high performance logic chip. A process flow for fabricating the structure is also disclosed. In accordance with a specific embodiment of the present invention, the combination of “thin vias” beneath the MTJs, the presence of an MRAM pedestal material beneath the MTJs, and an MTJ-first type process flow where the MTJs are fabricated prior to the interconnect in the neighboring logic area is disclosed.

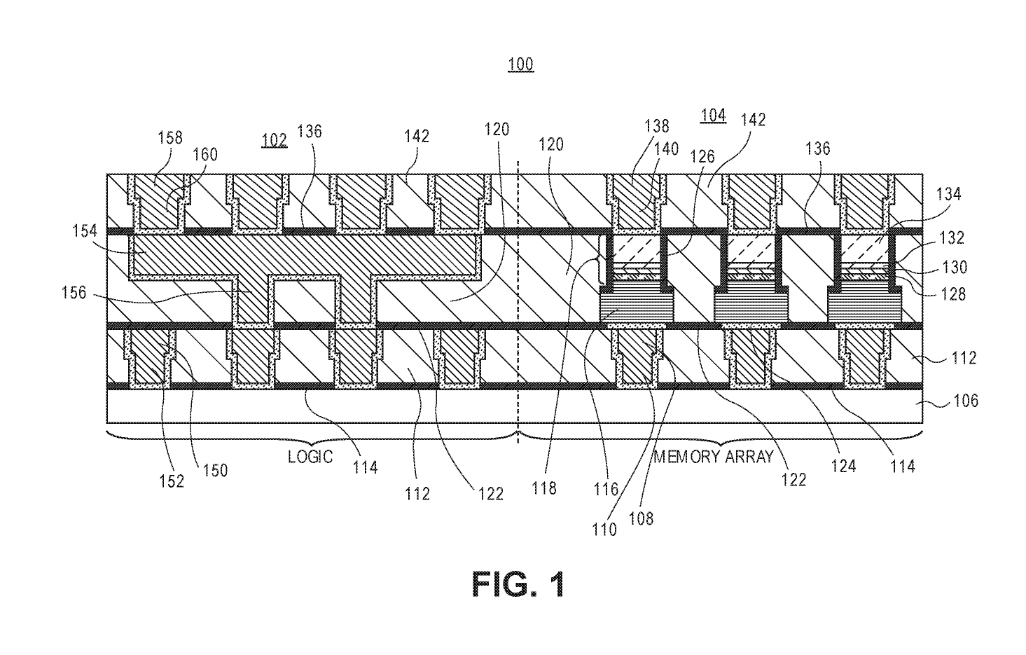

An STT-MRAM array may be embedded in a logic chip. As an example, FIG. 1 illustrates a cross-sectional view of a logic region together with a STT-MRAM memory array integrated on a common substrate, in accordance with an embodiment of the present invention. Referring to FIG. 1, a structure 100 includes a logic region 102 and a STT-MRAM array region 104.

Referring to the STT-MRAM array region 104 of FIG. 1, in a first layer, metal 2 (M2) 108 and via 1 (V1) 110 structures are formed above a substrate 106. The M2 108 and V1 110 structures are formed in an inter-layer dielectric layer 112 disposed over an etch stop layer 114.

Referring again to the STT-MRAM array region 104 of FIG. 1, in a second layer, a plurality of conductive pedestals 116 and corresponding an MTJ stacks 118 are formed in an inter-layer dielectric layer 120 disposed over an etch stop layer 122. The plurality of conductive pedestals 116 may be coupled to corresponding ones of the M2 108 structures by a conductive layer 124, as is depicted in FIG. 1. A dielectric spacer layer 126 may be formed on sidewalls of the MTJ stacks 118 and on the upper surface of the plurality of conductive pedestals 116, as is also depicted in FIG. 1. Each of the MTJ stacks 118 may include a free layer MTJ film or films 128, a dielectric or tunneling layer 130, a fixed layer MTJ film or films 132, and a top electrode 134, as is depicted in FIG. 1. It is to be appreciated that the stack may be reversed, in that layer 128 may be a fixed layer while layer 132 may be a free layer.

Referring again to the STT-MRAM array region 104 of FIG. 1, in a third layer, an etch stop layer 136 is disposed on the inter-layer dielectric layer 120. Metal 4 (M4) 138 and via to junction (VTJ) 140 structures are formed in an inter-layer dielectric layer 142 disposed over the etch stop layer 136. It is to be appreciated that additional interconnect layer(s) may be formed on top of the M4/VTJ layers of the STT-MRAM array region 104 of FIG. 1, e.g., using standard dual damascene process techniques that are well-known in the art.

It is to be appreciated that although the MTJs actually include multiple layers of very thin metal films, for the sake of simplicity the MTJ film stack is divided into 4 portions in FIG. 1: bottom MTJ films, tunnel barrier material, top MTJ films, and MTJ top electrode. It is also to be appreciated that although in the illustrations the MTJs are shown embedded into a corresponding logic metal 3 (M3) layer, they may instead be embedded into some other interconnect layer (e.g., M1, M2, M4, etc.)

Referring now to the logic region 102 of FIG. 1, in the first layer, metal 2 (M2) 150 and via 1 (V1) 152 structures are formed in the inter-layer dielectric layer 112 disposed over the etch stop layer 114. In the second layer, the etch stop layer 122 is disposed on the inter-layer dielectric layer 112. Metal 3 (M3) 154 and via 2 (V2) 156 structures are formed in the inter-layer dielectric layer 120 disposed over the etch stop layer 122. In the third layer, the etch stop layer 136 is disposed on the inter-layer dielectric layer 120. Metal 4 (M4) 158 and via 3 (V3) 160 structures are formed in the inter-layer dielectric layer 142 disposed over the etch stop layer 136. It is to be appreciated that additional interconnect layer(s) may be formed on top of the M4/V3 layers of the logic region 102 of FIG. 1, e.g., using standard dual damascene process techniques that are well-known in the art.

Referring again to FIG. 1, in an embodiment, the free layer MTJ film or films 128 (or, alternatively, 132) is composed of a material suitable for transitioning between a majority spin and a minority spin, depending on the application. Thus, the free magnetic layer (or memory layer) may be referred to as a ferromagnetic memory layer. In one embodiment, the free magnetic layer is composed of a layer of cobalt iron (CoFe) or cobalt iron boron (CoFeB).

Referring again to FIG. 1, in an embodiment, the dielectric or tunneling layer 130 is composed of a material suitable for allowing current of a majority spin to pass through the layer, while impeding at least to some extent current of a minority spin to pass through the layer. Thus, the dielectric or tunneling layer 130 (or spin filter layer) may be referred to as a tunneling layer. In one embodiment, the dielectric layer is composed of a material such as, but not limited to, magnesium oxide (MgO) or aluminum oxide (Al₂O₃). In one embodiment, the dielectric layer has a thickness of approximately 1 nanometer.

Referring again to FIG. 1, in an embodiment, the fixed layer MTJ film or films 132 (or 128 in the case that 132 is a free layer) is composed of a material or stack of materials suitable for maintaining a fixed majority spin. Thus, the fixed magnetic layer (or reference layer) may be referred to as a ferromagnetic layer. In one embodiment, the fixed magnetic layer is composed of a single layer of cobalt iron boron (CoFeB). However, in another embodiment, the fixed magnetic layer is composed of a cobalt iron boron (CoFeB) layer, ruthenium (Ru) layer, cobalt iron boron (CoFeB) layer stack. In an embodiment, although not depicted, a synthetic antiferromagnet (SAF) is disposed on or adjacent the fixed layer MTJ film or films 132.

Referring again to FIG. 1, in an embodiment, the plurality of conductive pedestals 116 includes a thick metal layer, such as a relatively thick titanium nitride (TiN) layer. In an embodiment, the conductive metal layer 124 is a tantalum nitride (TaN) layer. In one embodiment, the conductive metal layer 124 is referred to as a “thin via” layer.

Referring again to FIG. 1, in an embodiment, the top electrode 134 is composed of a material or stack of materials suitable for electrically contacting the fixed layer MTJ film or films 132. In an embodiment, the top electrode 134 is a topographically smooth electrode. In one such embodiment, the top electrode 134 has a thickness suitable for good conductivity but has little to no columnar structure formation that would otherwise lead to a rough top surface. Such a topographically smooth electrode may be referred to as amorphous in structure. In a specific embodiment, the top electrode 134 is composed of Ru layers interleaved with Ta layers. Effectively, in accordance with an embodiment of the present invention, the top electrode 134 may not be a conventional thick single metal electrode, such as a Ru electrode, but is instead a Ru/Ta interleaved materials stack. In alternative embodiments, however, the top electrode 134 is a conventional thick single metal electrode, such as a Ta or Ru electrode.

Referring again to FIG. 1, in an embodiment, one or more interlayer dielectrics (ILD), such as inter-layer dielectric material layers 112, 120 and 142, are used. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

Referring again to FIG. 1, in an embodiment, the metal lines (such as M2, M3, and M4) and vias (such as V1, V2, V3 and VTJ) are composed of one or more metal or other conductive structures. A common example is the use of copper lines and structures that may or may not include barrier layers between the copper and surrounding ILD material. As used herein, the term metal includes alloys, stacks, and other combinations of multiple metals. For example, the metal interconnect lines may include barrier layers, stacks of different metals or alloys, etc. The interconnect lines are also sometimes referred to in the arts as traces, wires, lines, metal, or simply interconnect.

Referring again to FIG. 1, in an embodiment, etch stop materials (such as for layers 114, 122 and 136, are composed of dielectric materials different from the interlayer dielectric material. In some embodiments, an etch stop layer includes a layer of a nitride of silicon (e.g., silicon nitride) or a layer of an oxide of silicon, or both, or a combination thereof. Other suitable materials may include carbon-based materials, such as silicon carbide. Alternatively, other etch stop layers known in the art may be used depending upon the particular implementation. The etch stop layers maybe formed by CVD, PVD, or by other deposition methods. In an embodiment, the dielectric spacer layer 126 is a silicon nitride layer.

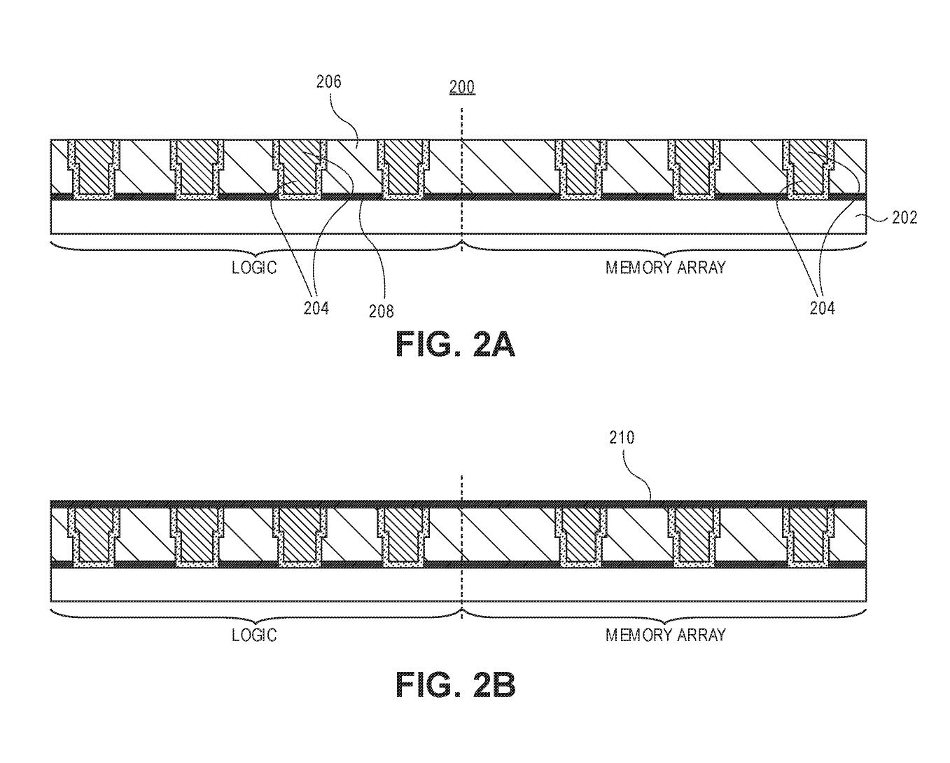

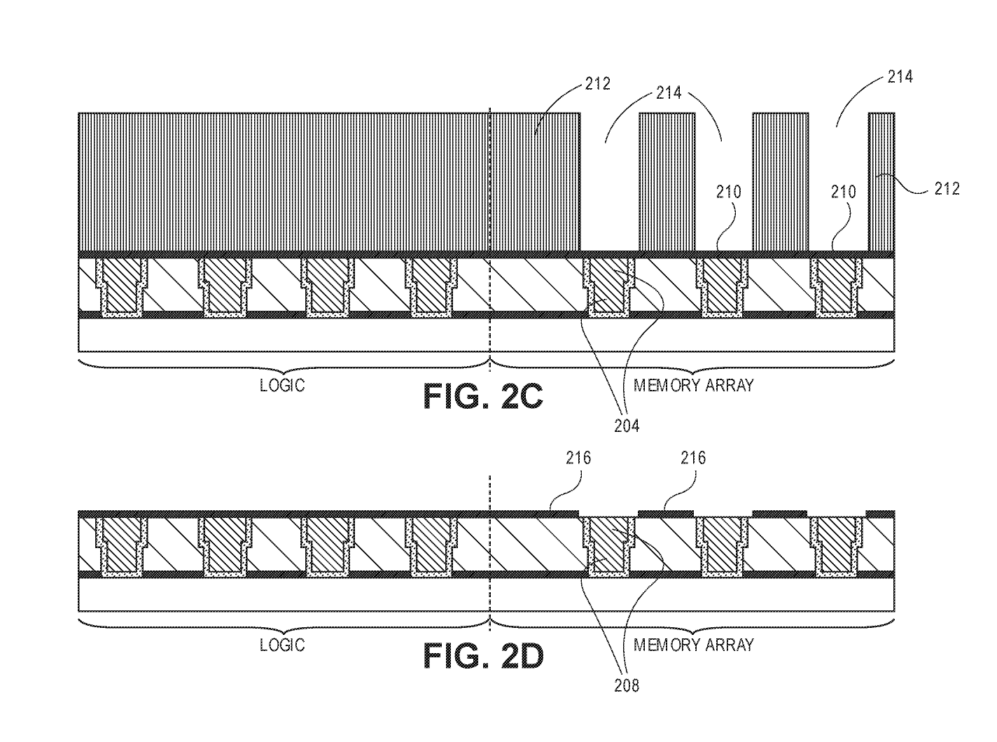

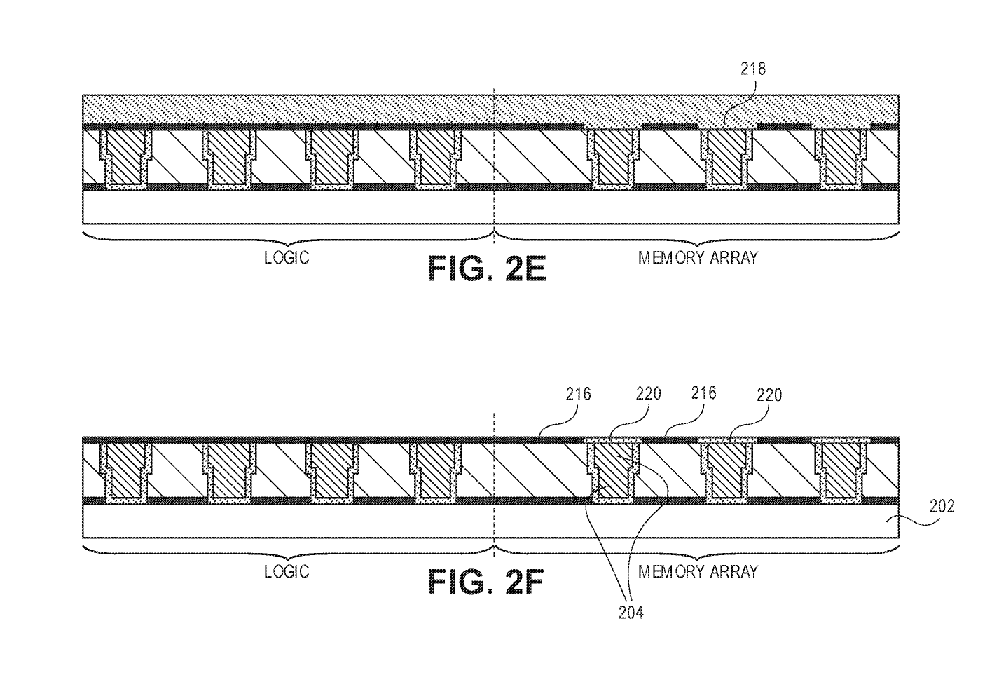

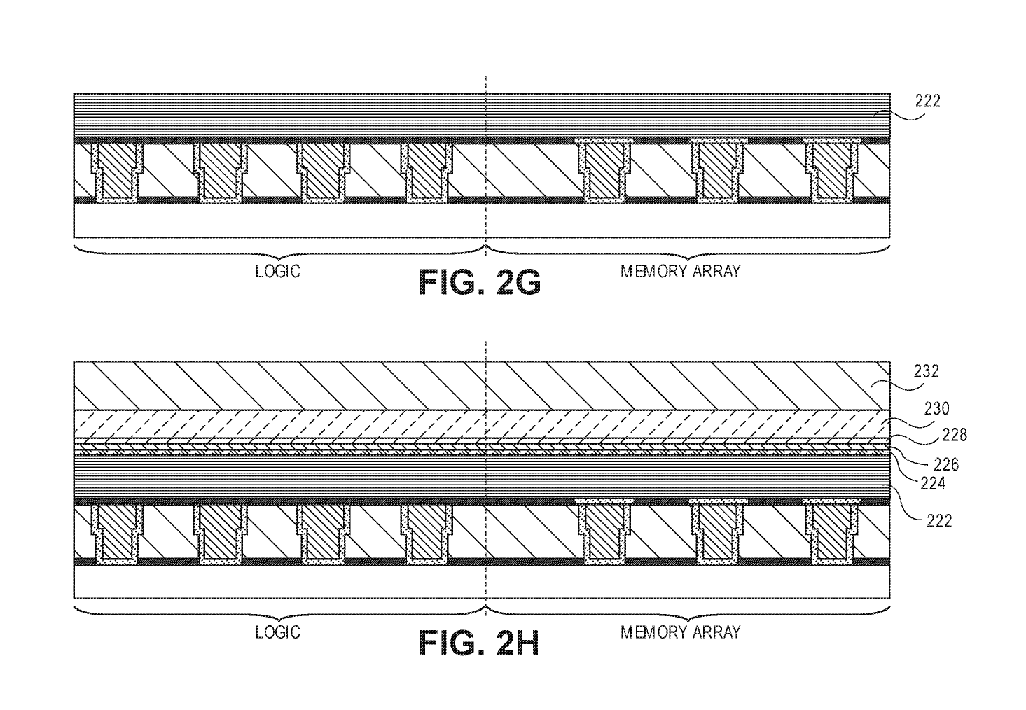

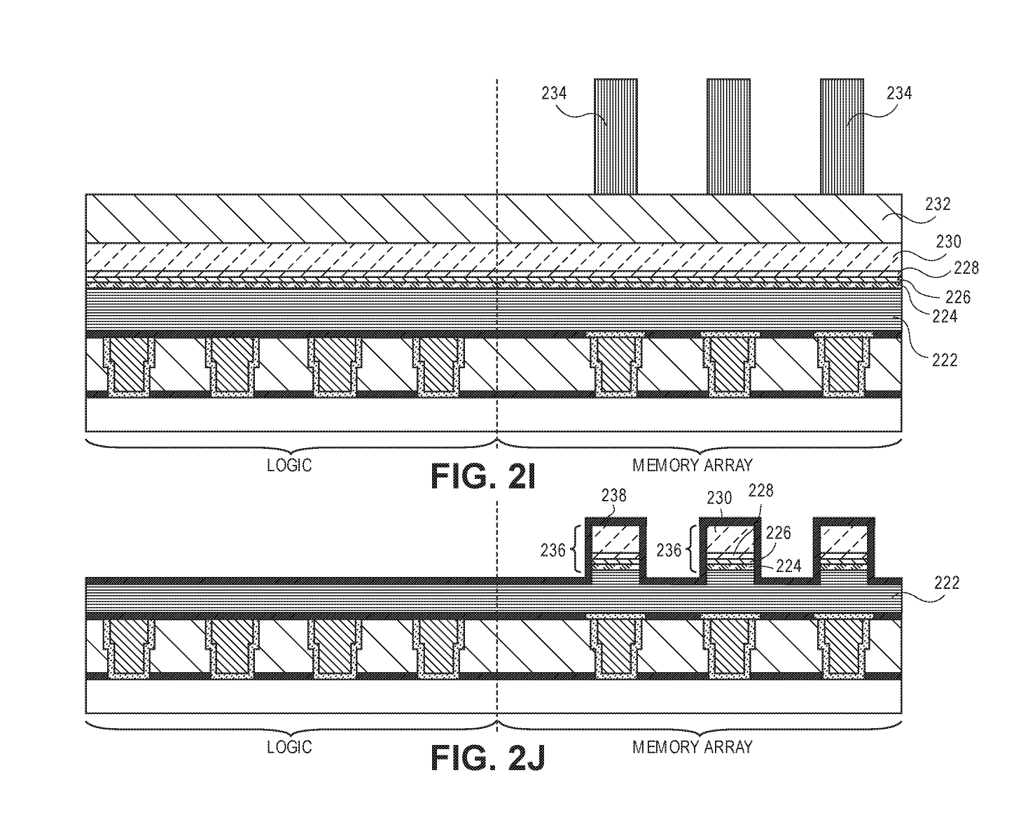

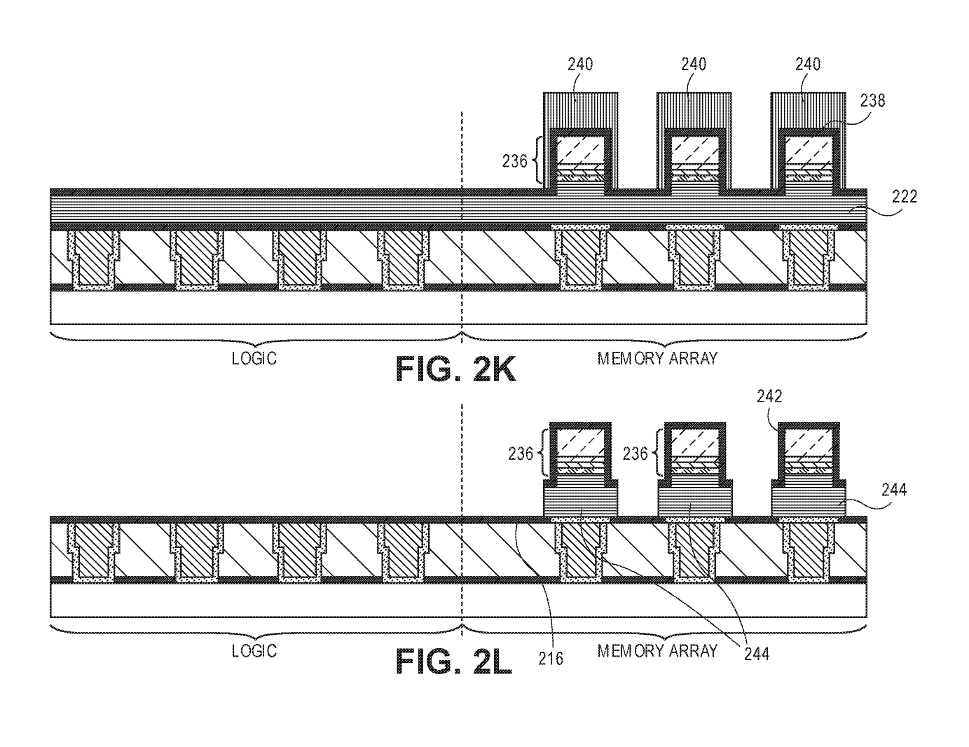

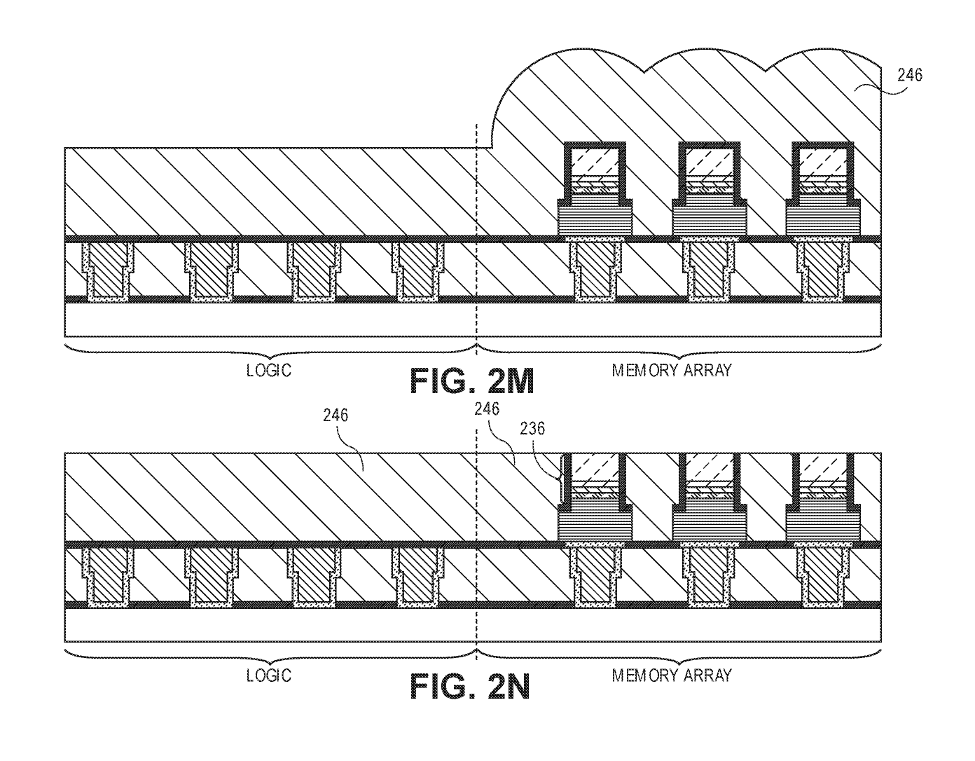

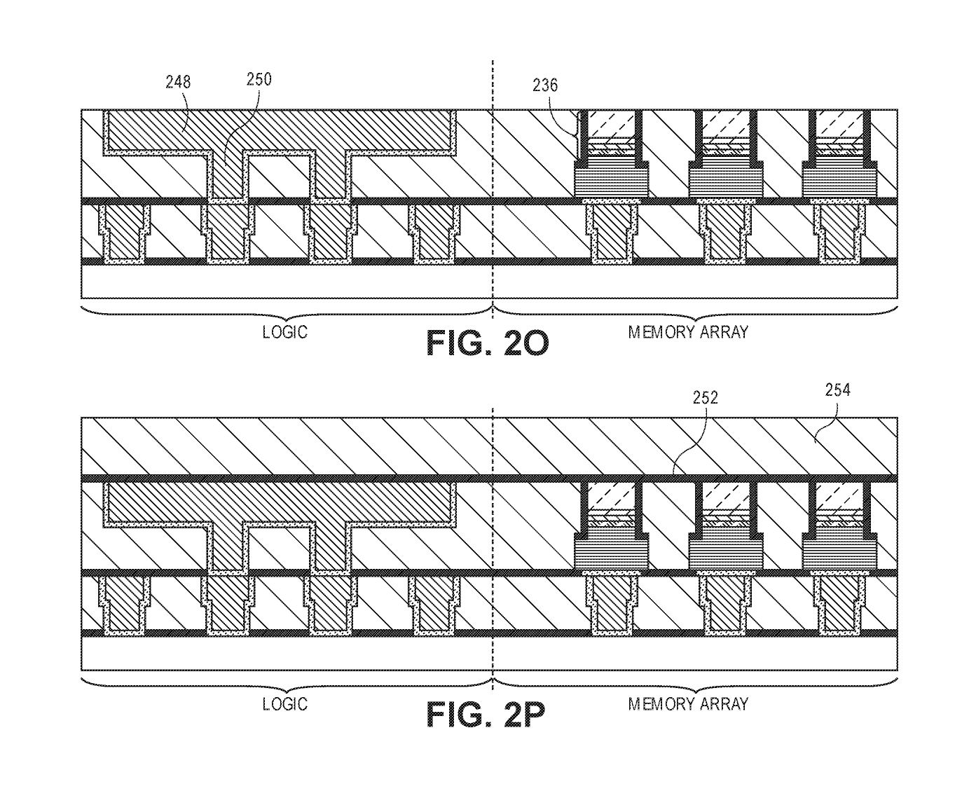

Referring again to FIG. 1, in an embodiment, substrate 106 (or substrate 202 described below in association with FIGS. 2A-2P) is a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

It is to be appreciated that the layers and materials described in association with FIGS. 1 and 2A-2P are typically formed on or above an underlying semiconductor substrate or structure, such as underlying device layer(s) of an integrated circuit. In an embodiment, an underlying semiconductor substrate 106 or 202 represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials. The semiconductor substrate, depending on the stage of manufacture, often includes transistors, integrated circuitry, and the like. The substrate may also include semiconductor materials, metals, dielectrics, dopants, and other materials commonly found in semiconductor substrates. In one embodiment, the illustrated structures depicted in FIGS. 1 and 2A-2P are fabricated on underlying transistor or other semiconductor device layer(s) formed in or above the substrate 106 or 202. In another embodiment, the illustrated structures depicted in FIGS. 1 and 2A-2P are fabricated on underlying lower level interconnect layers formed above the substrate 106 or 202.

A shared fabrication scheme may be implemented to embed a STT-MRAM array into a logic process technology. As an exemplary processing scheme, FIGS. 2A-2P illustrate cross-sectional views representing various processing operations in a method of fabricating logic regions together with STT-MRAM memory array integrated on a common substrate, in accordance with an embodiment of the present invention.

Referring to FIG. 2A, the fabrication approach begins with a starting structure 200 formed above a substrate 202. M2/V1 metallization 204 is formed in an inter-layer dielectric layer 206 above an etch stop layer 208. The M2/V1 metallization 204 may be fabricated using methods and techniques that are well-known in the art. The partially completed wafer is then processed through the following operations described in association with FIGS. 2B-2P. Logic regions and memory array regions are designated throughout. The process sequence begins with a substrate (e.g., a wafer) on which the topmost surface has a patterned interconnect layer. For the purposes of illustration the process flow is shown beginning with a wafer with a patterned metal 2 (M2) interconnect layer on its topmost surface, but the topmost surface could be some other interconnect layer (e.g., M1, M3, M4 etc.). The substrate may also have other back-end and/or front-end layers beneath the topmost patterned interconnect layers.

Referring to FIG. 2B, an etch stop layer 210 is formed over the structure of FIG. 2A. In an embodiment, the etch stop layer 210 is composed of silicon nitride, silicon carbide, or silicon oxynitride.

Referring to FIG. 2C, a photoresist layer 212 is formed and patterned over the structure of FIG. 2B. In an embodiment, after patterning, there are holes 214 in the photoresist layer 212 in locations where thin vias will ultimately connect a conductive pedestal layer to an underlying M2/V1 metallization 204. The photoresist layer 212 may include other patterning materials such as anti-reflective coatings (ARC's) and gap-fill and planarizing materials in addition to or in place of a photoresist material. Furthermore, an underlying hardmask material may also be present to aid in the subsequent transfer of the resist patterned to the underlying ILD in the next operation.

Referring to FIG. 2D, an anisotropic dry etch process is then used to transfer the resist pattern of the structure of FIG. 2C into the etch stop layer 210 to form a patterned etch stop layer 216. The patterned etch stop layer 216 exposes underlying M2/V1 metallization 204 on the memory array portion of the substrate 202. In an embodiment, any remaining resist 212 is removed using a plasma ash process and a cleans process may be used to remove any post-ash residue.

Referring to FIG. 2E, a conductive metal layer 218 is formed over the structure of FIG. 2D. In an embodiment, the conductive metal layer 218 is deposited onto the entire wafer surface, filling into the thin via openings and covering the entire wafer surface. Suitable materials for the conductive metal layer 218 may include titanium, tantalum, titanium nitride, tantalum nitride, ruthenium, titanium-zirconium nitride, cobalt, etc.

Referring to FIG. 2F, the structure of FIG. 2E is planarized to remove conductive metal overburden of the conductive metal layer 218 using a chemical mechanical planarization (CMP) process, stopping on the underlying patterned etch stop material 216, and leaving a metal layer 220 in openings of the patterned etch stop layer 216. Accordingly, after the CMP process is completed, conductive metal remains in the thin via openings but is completely removed from the remaining surface of the wafer. In an embodiment, the metal layer 220 contacts the underlying M2/V1 metallization 204 on the memory array region, as is depicted in FIG. 2F.

Referring to FIG. 2G, a pedestal metal layer 222 is formed over the structure of FIG. 2F. In an embodiment, the pedestal metal layer 222 is composed of a material such as, but not limited to, a layer of titanium nitride, tantalum nitride, tantalum, ruthenium, cobalt, etc.

Referring to FIG. 2H, MTJ free layer film(s) 224, tunnel barrier material 226, MTJ fixed layer film(s) 228, MTJ top electrode layer 230, and a MTJ hard mask film 232 are formed over the structure of FIG. 2G. In an embodiment, such layers are deposited onto the wafer using PVD, ALD, or CVD deposition techniques. The MTJ free layer film(s), tunnel barrier material, and MTJ fixed layer film(s) may be composed of materials such as those described above in association with FIG. 1.

Referring to FIG. 2I, a photoresist layer 234 is applied to the wafer surface and patterned over the structure of FIG. 2H. In an embodiment, after patterning photoresist layer 234 remains where MTJ stacks are to be located. The photoresist layer 234 may include other patterning materials such as anti-reflective coatings (ARC's) and gap-fill and planarizing materials in addition to or in place of a photoresist material. Additionally, an underlying hardmask material may also be present to aid in the subsequent transfer of the resist patterned to the underlying films in the next operation, as is well-known in the art.

Referring to FIG. 2J, portions of the MTJ hardmask 232, upper electrode layer 230, the MTJ fixed layer film(s) 228, the tunnel barrier material 226, and the MTJ free layer film(s) 224 that are not covered with the resist 234 of the structure of FIG. 2I are patterned to form a plurality of MTJ stack 236. In an embodiment, these layers are etched using RIE dry etch techniques known in the art, stopping (or at most partially etching into) on the pedestal metal layer 222. In one embodiment, prior to breaking vacuum in an etch chamber, the wafer surface is covered with a polish-stop material layer 238, such as a silicon nitride, silicon carbide, silicon oxynitride or carbon-doped silicon oxynitride layer. The polish-stop material layer 238 may serve two functions: (1) to protect the etched sidewalls of the MTJ fixed layer film(s), the tunnel barrier material, and the MTJ free layer film(s) from oxidation/corrosion and (2) to function as a polish stop during the subsequent ILD polish operation described below. In an embodiment, the processing described in this operation is conducted all in-situ in a large cluster tool without breaking vacuum, in order to minimize any chance of oxidation or corrosion of the MTJ devices. Also, in a specific embodiment, note the MTJ hardmask material 232 is completely consumed during the MTJ etch process.

Referring to FIG. 2K, a photoresist layer 240 is applied to the wafer surface and patterned. In an embodiment, after patterning, photoresist 240 remains only where patterned conductive pedestals will ultimately be formed. In one embodiment, photoresist 240 remains in the memory array areas at those locations where MTJ stack 236 are located. In a specific embodiment, the width of the resist 240 features is wider compared to the respective MTJ stack 236, so that the MTJ stacks 236 are protected during a subsequent MRAM pedestal etch process. The photoresist layer 240 may include other patterning materials such as anti-reflective coatings (ARC's) and gap-fill and planarizing materials in addition to or in place of a photoresist material. Additionally, an underlying hardmask material may also be present to aid in the subsequent transfer of the resist pattern to the underlying films in the next operation, as is well-known in the art.

Referring to FIG. 2L, an anisotropic dry etch process is then used to transfer the resist pattern 240 of the structure of FIG. 2K into the polish-stop material layer 238 and then into the pedestal metal layer 222 to form patterned polish-stop material layer 242 and conductive pedestals 244, stopping on the underlying etch stop layer 216. In an embodiment, any remaining resist is removed using a plasma ash process, and a cleans process may be used to remove any post-ash residue.

Referring to FIG. 2M, an interlayer dielectric (ILD) layer 246 is deposited over the structure of FIG. 2L. In an embodiment, the ILD layer 246 is formed to a thickness value suitable for forming a regular interconnect structure in the logic circuit areas. Suitable ILD materials may include an ILD material known in the art and having properties suitable for use in the logic circuits in the interconnect layer at hand, such as silicon dioxide, silicon nitride, fluorinated silicon oxide (SiOF), borophosphosilicate glass (BPSG), or a low k dielectric (e.g., k<3) such as carbon-doped oxide (CDO). In one embodiment, the ILD material 246 are deposited using CVD processes.

Referring to FIG. 2N, the ILD layer 246 formed in the operation described in association with FIG. 2M is planarized using CMP techniques. In one embodiment, the CMP process initially stops on etch stop layer on top of the MTJ devices, and then is removed during the final portion of the CMP process to expose the uppermost portion of the MTJ stack 236, as is depicted in FIG. 2N.

Referring to FIGS. 2O, M3 248 and V2 250 copper interconnect structures are formed in the logic areas of the structure of FIG. 2N. The M3/V2 248/250 copper interconnect structures may be fabricated using dual damascene trench and via patterning, barrier/seed dep, copper electroplate, and CMP processes.

Referring to FIG. 2P, an etch stop layer 252 and inter-layer dielectric layer 254 are formed on the structure of FIG. 2O. Suitable etch stop materials 252 may include silicon nitride, silicon carbide, silicon oxynitride or carbon-doped silicon oxynitride. The dielectric material 254 may consist of a silicon dioxide, silicon nitride, fluorinated silicon oxide (SiOF), borophosphosilicate glass (BPSG), or a low k dielectric (e.g., k<3) such as carbon-doped oxide (CDO).

Referring again now to FIG. 1, additional processing of the structure of FIG. 2P may include fabrication of M4/V3 copper interconnect structures in the logic region 102 and fabrication of M4/VTJ copper interconnect structures in the memory array 104. As described in association with FIG. 1, additional interconnect layer(s) may be formed on top of the M4/V3 and M4/VTJ layers of FIG. 1, e.g., using standard dual damascene process trench and via patterning, barrier/seed dep, copper electroplate, and CMP processes, as are well-known in the art. Additionally, it is to be appreciated that additional copper interconnect layer(s) may be formed on top of the M4/V3 layers, as desired, using standard dual damascene process techniques that are well-known in the art.

Although the above method of fabricating a STT-MRAM array embedded in a logic chip has been described in detail with respect to select operations, it is to be appreciated that additional or intermediate operations for fabrication may include standard microelectronic fabrication processes such as lithography, etch, thin films deposition, planarization (such as chemical mechanical polishing (CMP)), diffusion, metrology, the use of sacrificial layers, the use of etch stop layers, the use of planarization stop layers, and/or any other associated action with microelectronic component fabrication.

It is also to be appreciated that in certain aspects and at least some embodiments of the present invention, certain terms hold certain definable meanings. For example, a “free” magnetic layer is a magnetic layer storing a computational variable. A “fixed” magnetic layer is a magnetic layer with fixed magnetization (magnetically harder than the free magnetic layer). A tunneling barrier, such as a tunneling dielectric or tunneling oxide, is one located between free and fixed magnetic layers. A fixed magnetic layer may be patterned to create inputs and outputs to an associated circuit. Magnetization may be written by spin hall effect. Magnetization may be read via the tunneling magneto-resistance effect while applying a voltage. In an embodiment, the role of the dielectric layer is to cause a large magneto-resistance ratio. The magneto-resistance is the ratio of the difference between resistances when the two ferromagnetic layers have anti-parallel magnetizations and the resistance of the state with the parallel magnetizations.

In an embodiment, the MTJ functions essentially as a resistor, where the resistance of an electrical path through the MTJ may exist in two resistive states, either “high” or “low,” depending on the direction or orientation of magnetization in the free magnetic layer and in the fixed magnetic layer. In the case that the spin direction is of minority in the free magnetic layer, a high resistive state exists, wherein direction of magnetization in the free magnetic layer and the fixed magnetic layer are substantially opposed or anti-parallel with one another. In the case that the spin direction is of majority in the free magnetic layer, a low resistive state exists, wherein the direction of magnetization in the free magnetic layer and the fixed magnetic layer is substantially aligned or parallel with one another. It is to be understood that the terms “low” and “high” with regard to the resistive state of the MTJ are relative to one another. In other words, the high resistive state is merely a detectibly higher resistance than the low resistive state, and vice versa. Thus, with a detectible difference in resistance, the low and high resistive states can represent different bits of information (i.e. a “0” or a “1”).

Thus, the MTJ may store a single bit of information (“0” or “1”) by its state of magnetization. The information stored in the MTJ is sensed by driving a current through the MTJ. The free magnetic layer does not require power to retain its magnetic orientations. As such, the state of the MTJ is preserved when power to the device is removed. Therefore, a memory bit cell such as depicted in FIG. 1 is, in an embodiment, non-volatile.

In accordance with an embodiment of the present invention, each bit of data is stored in a separate magnetic tunnel junction (MTJ). The MTJ is a magnetic element that includes two magnetic layers separated by a thin insulating tunnel barrier layer. One of the magnetic layers is referred to as the reference layer, the fixed layer, or the pinned magnetic layer, and it provides a stable reference magnetic orientation. The bit is stored in the second magnetic layer which is called the free layer, and the orientation of the magnetic moment of the free layer can be either in one of two states—parallel to the reference layer or anti-parallel to the reference layer. Because of the tunneling magneto-resistance (TMR) effect, the electrical resistance of the anti-parallel state is significantly higher compared to the parallel state. To write information in a STT-MRAM device, the spin transfer torque effect is used to switch the free layer from the parallel to anti-parallel state and vice versa. The passing of current through the MTJ produces spin polarized current, which results in a torque being applied to the magnetization of the free layer. When the spin polarized current is sufficiently strong, enough torque is applied to the free layer to cause its magnetic orientation to change, thus allowing for bits to be written. To read the stored bit, the sensing circuitry measures the resistance of the MTJ. Since the sensing circuitry needs to determine whether the MTJ is in the low resistance (e.g. parallel) state or in the high resistance state (e.g. anti-parallel) with acceptable signal-to-noise, the STT-MRAM cell needs to be designed such that the overall electrical resistance and resistance variation of the cell are minimized.

Relating to one or more embodiments described herein, it is to be appreciated that traditional DRAM memory is facing severe scaling issues and, so, other types of memory devices are being actively explored in the electronics industry. One future contender is STT-MRAM devices. Embodiments described herein include a fabrication method for embedding STT-MRAM bit cell arrays into a logic process technology. Embodiments described may be advantageous for processing schemes involving the fabrication of logic processors with embedded memory arrays.

In an embodiment, transistors associated with substrate 106 or 202 are metal-oxide-semiconductor field-effect transistors (MOSFET or simply MOS transistors), fabricated on the substrate 106 or 202. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors.

In an embodiment, each MOS transistor of substrate 106 or 202 includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer of each MOS transistor of substrate 106 or 202 is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

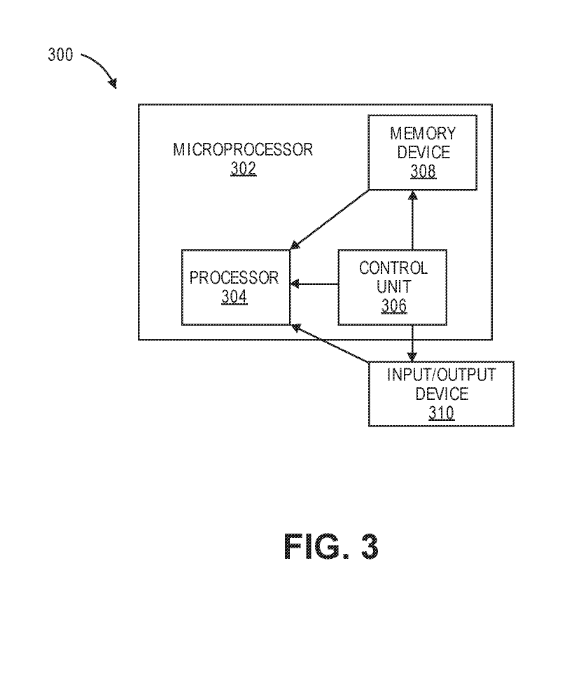

FIG. 3 illustrates a block diagram of an electronic system 300, in accordance with an embodiment of the present invention. The electronic system 300 can correspond to, for example, a portable system, a computer system, a process control system, or any other system that utilizes a processor and an associated memory. The electronic system 300 may include a microprocessor 302 (having a processor 304 and control unit 306), a memory device 308, and an input/output device 310 (it is to be understood that the electronic system 300 may have a plurality of processors, control units, memory device units and/or input/output devices in various embodiments). In one embodiment, the electronic system 300 has a set of instructions that define operations which are to be performed on data by the processor 304, as well as, other transactions between the processor 304, the memory device 308, and the input/output device 310. The control unit 306 coordinates the operations of the processor 304, the memory device 308 and the input/output device 310 by cycling through a set of operations that cause instructions to be retrieved from the memory device 308 and executed. The memory device 308 can include STT-MRAM memory arrays integrated into a logic processor, as described herein. In an embodiment, the memory device 308 is embedded in the microprocessor 302, as depicted in FIG. 3.

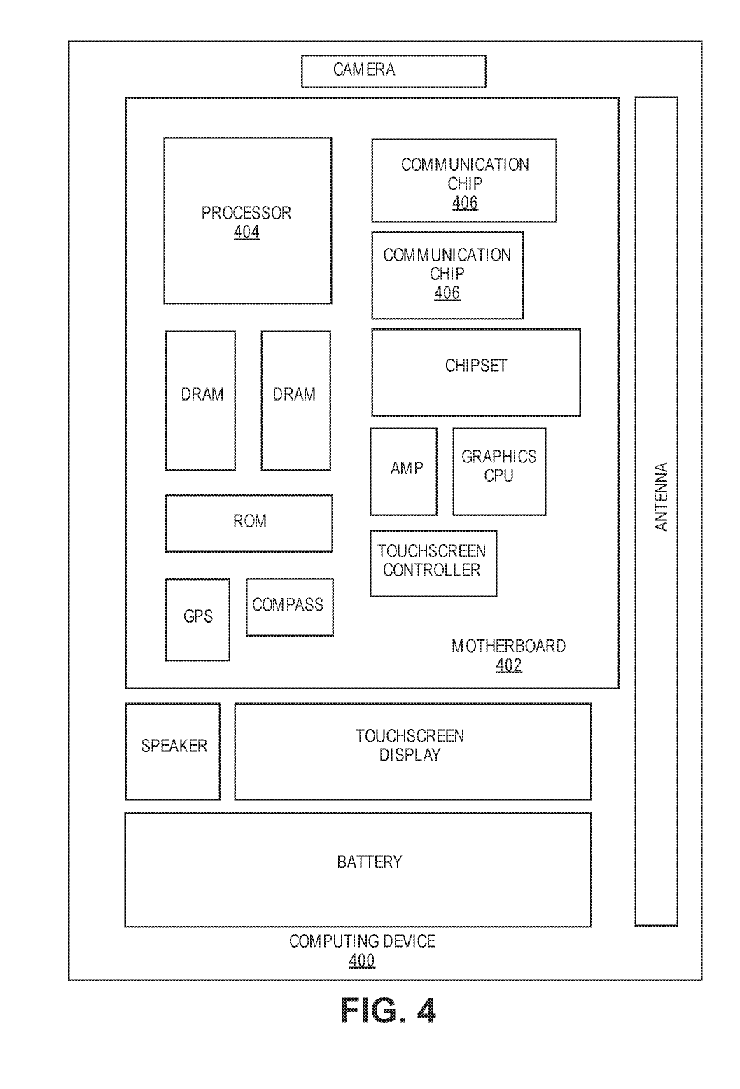

FIG. 4 illustrates a computing device 400 in accordance with one embodiment of the invention. The computing device 400 houses a board 402. The board 402 may include a number of components, including but not limited to a processor 404 and at least one communication chip 406. The processor 404 is physically and electrically coupled to the board 402. In some implementations the at least one communication chip 406 is also physically and electrically coupled to the board 402. In further implementations, the communication chip 406 is part of the processsor 404.

Depending on its applications, computing device 400 may include other components that may or may not be physically and electrically coupled to the board 402. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 406 enables wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

The processor 404 of the computing device 400 includes an integrated circuit die packaged within the processor 404. In some implementations of embodiments of the invention, the integrated circuit die of the processor includes one or more arrays, such as STT-MRAM memory arrays integrated into a logic processor, built in accordance with embodiments of the present invention. The term “processor” may refer to any device or portion of a device that processes electronic data from registers and/or memory to transform that electronic data into other electronic data that may be stored in registers and/or memory.

The communication chip 406 also includes an integrated circuit die packaged within the communication chip 406. In accordance with another implementation of an embodiment of the invention, the integrated circuit die of the communication chip includes STT-MRAM memory arrays integrated into a logic processor, built in accordance with embodiments of the present invention.

In further implementations, another component housed within the computing device 400 may contain a stand-alone integrated circuit memory die that includes one or more arrays, such as STT-MRAM memory arrays integrated into a logic processor, built in accordance with embodiments of the present invention.

In various implementations, the computing device 400 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 400 may be any other electronic device that processes data.

Accordingly, one or more embodiments of the present invention relate generally to the fabrication of embedded microelectronic memory. The microelectronic memory may be non-volatile, wherein the memory can retain stored information even when not powered. One or more embodiments of the present invention relate to the fabrication of STT-MRAM memory arrays integrated into a logic processor. Such arrays may be used in an embedded non-volatile memory, either for its non-volatility, or as a replacement for embedded dynamic random access memory (eDRAM). For example, such an array may be used for 1T-1X memory or 2T-1X memory (X=capacitor or resistor) at competitive cell sizes within a given technology node.

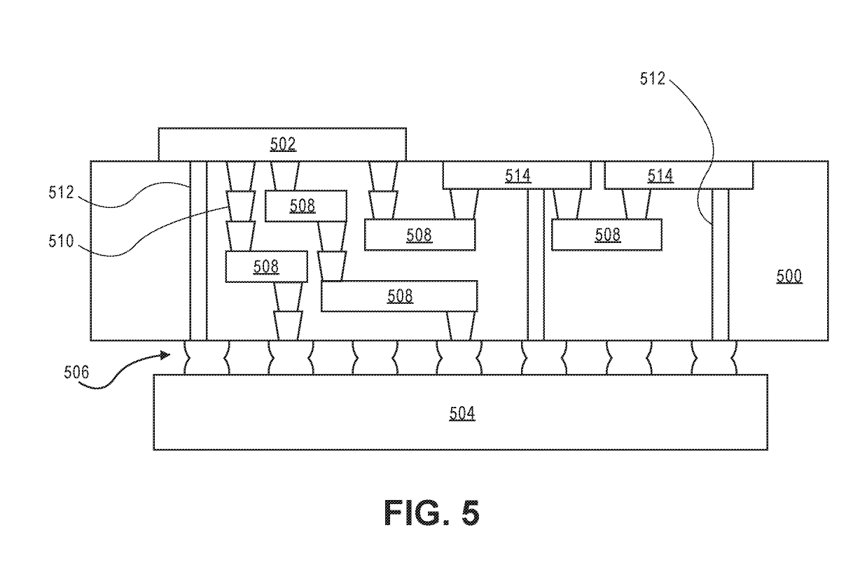

FIG. 5 illustrates an interposer 500 that includes one or more embodiments of the invention. The interposer 500 is an intervening substrate used to bridge a first substrate 502 to a second substrate 504. The first substrate 502 may be, for instance, an integrated circuit die. The second substrate 504 may be, for instance, a memory module, a computer motherboard, or another integrated circuit die. Generally, the purpose of an interposer 500 is to spread a connection to a wider pitch or to reroute a connection to a different connection. For example, an interposer 500 may couple an integrated circuit die to a ball grid array (BGA) 506 that can subsequently be coupled to the second substrate 504. In some embodiments, the first and second substrates 502/504 are attached to opposing sides of the interposer 500. In other embodiments, the first and second substrates 502/504 are attached to the same side of the interposer 500. And in further embodiments, three or more substrates are interconnected by way of the interposer 500.

The interposer 500 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 508 and vias 510, including but not limited to through-silicon vias (TSVs) 512. The interposer 500 may further include embedded devices 514, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 500. In accordance with embodiments of the invention, apparatuses or processes disclosed herein may be used in the fabrication of interposer 500.

Thus, embodiments of the present invention include approaches for integrating spin torque transfer magnetic random access memory (STT-MRAM) memory arrays into a logic processor, and the resulting structures.

In an embodiment, a logic processor including a logic region including metal line/via pairings disposed in a dielectric layer disposed above a substrate. The logic processor also includes a spin torque transfer magnetoresistive random access memory (STT-MRAM) array including a plurality of magnetic tunnel junctions (MTJs). The MTJs are disposed in the dielectric layer.

In one embodiment, each of the plurality of MTJs is disposed on a corresponding one of a plurality of conductive pedestals disposed in the dielectric layer.

In one embodiment, each of the plurality of conductive pedestals is disposed on a corresponding one of a plurality of thin vias electrically coupled to an underlying metallization layer of the STT-MRAM array.

In one embodiment, the plurality of thin vias is disposed in an etch stop layer disposed between the dielectric layer and a dielectric layer of the underlying metallization layer.

In one embodiment, the plurality of thin vias includes a material selected from the group consisting of titanium, tantalum, titanium nitride, tantalum nitride, ruthenium, titanium-zirconium nitride and cobalt.

In one embodiment, each of the plurality of conductive pedestals includes a material selected from the group consisting of titanium nitride, tantalum nitride, tantalum, ruthenium and cobalt.

In one embodiment, each of the plurality of conductive pedestals is wider than the corresponding one of the plurality of MTJs disposed thereon.

In one embodiment, the logic process further includes a dielectric spacer layer disposed along sidewalls of each of the plurality of MTJs.

In one embodiment, the dielectric spacer layer extends onto exposed top surfaces of each of the plurality of conductive pedestals.

In one embodiment, the logic region includes a plurality of metal 3 (M3) line/via 2 (V2) pairings disposed in the dielectric layer.

In an embodiment, a semiconductor structure includes a plurality of metal 2 (M2) line/via 1 (V1) pairings disposed in a first dielectric layer disposed above a substrate. The semiconductor structure also includes a plurality of metal 3 (M3) line/via 2 (V2) pairings and a plurality of magnetic tunnel junctions (MTJs) disposed in a second dielectric layer disposed above the first dielectric layer, the plurality of M3/V2 pairings coupled to a first portion of the plurality of M2/V1 pairings, and the plurality of MTJs coupled to a second portion of the plurality of M2/V1 pairings. The semiconductor structure also includes a plurality of metal 4 (M4) line/via 3 (V3) pairings and a plurality of metal 4 (M4) line/via to junction (VTJ) pairings disposed in a third dielectric layer disposed above the second dielectric layer, the plurality of M4/V3 pairings coupled to the plurality of M3/V2 pairings, and the plurality of M4/VTJ pairings coupled to the plurality of MTJs.

In one embodiment, each of the plurality of MTJs is disposed on a corresponding one of a plurality of conductive pedestals disposed in the second dielectric layer.

In one embodiment, each of the plurality of conductive pedestals is disposed on a corresponding one of a plurality of thin vias electrically coupled to the second portion of the plurality of M2/V1 pairings.

In one embodiment, the plurality of thin vias is disposed in an etch stop layer disposed between the first dielectric layer and the second dielectric layer.

In one embodiment, the semiconductor further includes a second etch stop layer disposed between the second and third dielectric layers.

In one embodiment, the plurality of thin vias includes a material selected from the group consisting of titanium, tantalum, titanium nitride, tantalum nitride, ruthenium, titanium-zirconium nitride and cobalt.

In one embodiment, each of the plurality of conductive pedestals includes a material selected from the group consisting of titanium nitride, tantalum nitride, tantalum, ruthenium and cobalt.

In one embodiment, each of the plurality of conductive pedestals is wider than the corresponding one of the plurality of MTJs disposed thereon.

In one embodiment, the semiconductor structure further includes a dielectric spacer layer disposed along sidewalls of each of the plurality of MTJs.

In one embodiment, the dielectric spacer layer extends onto exposed top surfaces of each of the plurality of conductive pedestals.

In an embodiment, a method of fabricating logic regions together with an STT-MRAM array on a common substrate includes forming a metallization layer above a substrate, forming a conductive metal layer and magnetic tunnel junction (MTJ) stack layers above the metallization layer, patterning the MTJ stack layers to form a plurality of MTJ elements, subsequent to patterning the MTJ stack layers patterning the conductive metal layer to form a plurality of conductive pedestals corresponding to the plurality of MTJ elements, forming and planarizing a dielectric layer over the plurality of MTJ elements, subsequent to forming and planarizing the dielectric layer forming a plurality of metal line/via pairings in a region of the dielectric layer laterally adjacent to the plurality of MTJ elements.

In one embodiment, patterning the conductive metal layer to form the plurality of conductive pedestals includes patterning the conductive metal layer to form the plurality of conductive pedestals each having a width greater than a width of a corresponding one of the plurality of MTJ elements.

In one embodiment, the method further includes, prior to forming the conductive metal layer and the magnetic tunnel junction (MTJ) stack layers, forming thin conductive vias above the metallization layer, wherein the conductive metal layer is formed on the thin conductive vias.

In one embodiment, forming the thin conductive vias includes forming an etch stop layer above the metallization layer, forming openings the etch stop layer to expose portions of the metallization layer, and forming and planarizing a conductive layer in the openings of the etch stop layer.

What is claimed is:

1. A logic processor, comprising:
a logic region comprising metal line/via pairings disposed in a dielectric layer disposed above a substrate; and
a spin torque transfer magnetoresistive random access memory (STT-MRAM) array comprising a plurality of magnetic tunnel junctions (MTJs), the MTJs disposed in the dielectric layer.

2. The logic processor of claim 1, wherein each of the plurality of MTJs is disposed on a corresponding one of a plurality of conductive pedestals disposed in the dielectric layer.

3. The logic processor of claim 2, wherein each of the plurality of conductive pedestals is disposed on a corresponding one of a plurality of thin vias electrically coupled to an underlying metallization layer of the STT-MRAM array.

4. The logic processor of claim 3, wherein the plurality of thin vias is disposed in an etch stop layer disposed between the dielectric layer and a dielectric layer of the underlying metallization layer.

5. The logic processor of claim 3, wherein the plurality of thin vias comprises a material selected from the group consisting of titanium, tantalum, titanium nitride, tantalum nitride, ruthenium, titanium-zirconium nitride and cobalt.

6. The logic processor of claim 2, wherein each of the plurality of conductive pedestals comprises a material selected from the group consisting of titanium nitride, tantalum nitride, tantalum, ruthenium and cobalt.

7. The logic processor of claim 2, wherein each of the plurality of conductive pedestals is wider than the corresponding one of the plurality of MTJs disposed thereon.

8. The logic process of claim 7, further comprising:
a dielectric spacer layer disposed along sidewalls of each of the plurality of MTJs.

9. The logic processor of claim 8, wherein the dielectric spacer layer extends onto exposed top surfaces of each of the plurality of conductive pedestals.

10. The logic processor of claim 1, wherein the logic region comprises a plurality of metal 3 line/via 2 pairings disposed in the dielectric layer.

11. A semiconductor structure, comprising:
a plurality of metal 2 (M2) line/via 1 (V1) pairings disposed in a first dielectric layer disposed above a substrate;
a plurality of metal 3 (M3) line/via 2 (V2) pairings and a plurality of magnetic tunnel junctions (MTJs) disposed in a second dielectric layer disposed above the first dielectric layer, the plurality of M3/V2 pairings coupled to a first portion of the plurality of M2/V1 pairings, and the plurality of MTJs coupled to a second portion of the plurality of M2/V1 pairings; and
a plurality of metal 4 (M4) line/via 3 (V3) pairings and a plurality of metal 4 (M4) line/via to junction (VTJ) pairings disposed in a third dielectric layer disposed above the second dielectric layer, the plurality of M4/V3 pairings coupled to the plurality of M3/V2 pairings, and the plurality of M4/VTJ pairings coupled to the plurality of MTJs.

12. The semiconductor structure of claim 11, wherein each of the plurality of MTJs is disposed on a corresponding one of a plurality of conductive pedestals disposed in the second dielectric layer.

13. The semiconductor structure of claim 12, wherein each of the plurality of conductive pedestals is disposed on a corresponding one of a plurality of thin vias electrically coupled to the second portion of the plurality of M2/V1 pairings.

14. The semiconductor structure of claim 13, wherein the plurality of thin vias is disposed in an etch stop layer disposed between the first dielectric layer and the second dielectric layer.

15. The semiconductor structure of claim 14, further comprising:
a second etch stop layer disposed between the second and third dielectric layers.

16. The semiconductor structure of claim 13, wherein the plurality of thin vias comprises a material selected from the group consisting of titanium, tantalum, titanium nitride, tantalum nitride, ruthenium, titanium-zirconium nitride and cobalt.

17. The semiconductor structure of claim 12, wherein each of the plurality of conductive pedestals comprises a material selected from the group consisting of titanium nitride, tantalum nitride, tantalum, ruthenium and cobalt.

18. The semiconductor structure of claim 12, wherein each of the plurality of conductive pedestals is wider than the corresponding one of the plurality of MTJs disposed thereon.

19. The semiconductor structure of claim 18, further comprising:
a dielectric spacer layer disposed along sidewalls of each of the plurality of MTJs.

20. The semiconductor structure of claim 19, wherein the dielectric spacer layer extends onto exposed top surfaces of each of the plurality of conductive pedestals.

21. A method of fabricating logic regions together with STT-MRAM arrays on a common substrate, the method comprising:
forming a metallization layer above a substrate;
forming a conductive metal layer and magnetic tunnel junction (MTJ) stack layers above the metallization layer;
patterning the MTJ stack layers to form a plurality of MTJ elements;
subsequent to patterning the MTJ stack layers, patterning the conductive metal layer to form a plurality of conductive pedestals corresponding to the plurality of MTJ elements;
forming and planarizing a dielectric layer over the plurality of MTJ elements; and
subsequent to forming and planarizing the dielectric layer, forming a plurality of metal line/via pairings in a region of the dielectric layer laterally adjacent to the plurality of MTJ elements.

22. The method of claim 21, wherein patterning the conductive metal layer to form the plurality of conductive pedestals comprises patterning the conductive metal layer to form the plurality of conductive pedestals each having a width greater than a width of a corresponding one of the plurality of MTJ elements.

23. The method of claim 21, further comprising:
prior to forming the conductive metal layer and the magnetic tunnel junction (MTJ) stack layers, forming thin conductive vias above the metallization layer, wherein the conductive metal layer is formed on the thin conductive vias.

24. The method of claim 23, wherein forming the thin conductive vias comprises:
forming an etch stop layer above the metallization layer;
forming openings the etch stop layer to expose portions of the metallization layer; and
forming and planarizing a conductive layer in the openings of the etch stop layer.
